(19) United States
(12) Patent Application Publication
(10) Pub. No.: US 2008/0283733 A1
(43) Pub. Date: Nov. 20, 2008

(54) Contactless switches

(76) Inventors: Laruent Tupinier, Reichstett (FR); Olivier R. Marroux, Biard (FR)

Correspondence Address: DELPHI TECHNOLOGIES, INC., M/C 480-410-202, PO BOX 5052, TROY, MI, 48007, US

(21) Appl. No.: 11/805,355

(22) Filed: May 23, 2007

(30) Foreign Application Priority Data
May 31, 2006 (EP) 06360022.5

(51) Int. Cl. H03K 17/78; G02B 5/32

(52) U.S. Cl. 250/214 SW; 359/15

(57) ABSTRACT

Switch including a support control organ in motion relative to a fixed device, the organ and the support being in such a relationship that a plurality of distinct relative positions produce differentiatable data producing different effects. One of the organ or the support includes at least one laser diode emitting a light beam and at least one photodetector, the other including a least one zone situated in the path of the laser beam and provided with computer-generated holograms forming elementary coding cells in order to perform spatial coding of the relative organ/support position. The beam sent by the laser diode is diffracted by the holograms in order to form a binary optical code which can be read by the photodetector and directly and instantaneously transformed into a binary electronic code.

### TECHNICAL FIELD

The present invention relates to a contactless switch conventionally including a control organ in movement relative to a fixed support, the organ and the support being in such a relationship that a plurality of distinct relative positions generate differentiatable data producing different effects.

### BACKGROUND OF THE INVENTION

At the present time, switching or controlling are generally performed by means of levers or buttons, which actuate slides, contacts, or rollers. This is, for example, the case in steering wheel controls of motor vehicles. Consequently, there is always a physical link between the elements, which link causes a certain wear and reduces the reliability of the devices in the long term.

### SUMMARY OF THE INVENTION

The aim of the present invention is to remedy these disadvantages.

The switch of the invention therefore proposes a solution which dispenses with all physical contact and is principally characterised by the fact that one of the organ or the support includes at least one laser diode emitting a light beam and at least one photodetector, the other including at least one zone situated in the path of the laser beam and provided with computer-generated holograms forming elementary coding cells in order to perform spatial coding of the relative organ/support position, the beam sent by the laser diode being diffracted by the holograms in order to form a binary optical code which can be read by the photodetector and directly and instantaneously transformed into a binary electronic code.

Such an optical switching system, not causing any wear and consequently improving the reliability of the switch, results from the use of a light beam associated with holograms in fact forming elementary coding cells. At the present time, it is known to manufacture coding cells of very small size, of the order of 30 μm to 50 μm, which permits multiplication of the coding positions even in switches of small size. This being so, in the majority of cases the switches operate with a restricted number of discrete positions, and it is consequently unnecessary to use cells having dimensions of this order of magnitude.

The possibility of using larger cells guarantees good reading a fortiori, while dispensing at the same stroke with problems associated with dust, possible scratches, vibrations and other mechanical unknown quantities encountered in the fields of use of switches, and more particularly in the motor vehicle.

The major advantage of the use of holograms resides, moreover, in the possibility of obtaining binary optical code directly, instantaneously available at the output of a conventional photodetector in the form of a binary electronic code, i.e. formed of distinct electrical signals which can alternatively adopt the level 0 and the level 1.

In accordance with the invention, the detector is then connected for example to a micro-controller, which manages the primary data emanating from the different electronic signals and converts them into secondary data permitting implementation of the effects associated with the different positions of the switch.

Certain configurations require the laser beam to pass through guiding/orientation components. Then the optical circuit simply has to be completed for the laser signal, once processed by the optical computer formed by the holograms of the coding cells, to be directed to the photodetector in order to process the data.

The use of optical technology provides contactless switch configurations of very varied forms and uses. Thus, in accordance with one possible configuration, the photodetector and the laser diode can be arranged on a fixed plate surrounded by a rotary drum made of light-guiding material, the ends of which are bevelled and reflect light. The laser diode and the photodetector are for example so located on the fixed plate that the beam from the diode is sent to the photodetector after two reflections on the reflective bevelled ends, an annular track of holograms being placed inside the drum in the path of the laser beam.

This configuration creates a rotary switch of ring type, such as those which can be found in the vicinity of the ends of steering wheel levers.

In this case, the annular track can be located between the laser diode and the first reflection.

Preferably, the holograms are here combined with a grating of diffractive lenses.

In accordance with a possible alternative, the switches which can be produced rather have a translative configuration. In this case, in accordance with one possibility, the switch of the invention includes a fixed diode, light-dividing component, hologram support and photodetector, the hologram support being formed of a material transparent to light and acting as a guide rail for a slide provided with a mirror reflecting light, the laser beam being divided into a plurality of beams directed towards the rail of the slide while passing through a track of holograms orientated along the slide axis, at least one of the said beams being reflected to the photodetector depending on the position of the slide.

Such switches can for example be used to increase the amplitude of a signal, in the manner of a potentiometer.

In accordance with one possibility, the light-dividing component can be a dividing grating. A possible modification can dispense with the dividing component and then be composed of a laser diode, a light-transparent organ including a slide rail guiding a slide, the face of which orientated towards the diode includes a track of holograms orientated along the slide axis, the elementary cells of the holograms then simultaneously performing coding and deflection towards the photodetector.

In this configuration, the holograms of the coding cells can for example be combined with a grating of refractive lenses.

Application of the same principle to a rotary switch is also quite possible. In this case, in accordance with a possible configuration, the switch can include at least one circular section of the type of a portion of a steering wheel, having a rotary motion, on which a track of holograms is placed, the diode emitting a beam substantially orientated parallel with the axis of rotation and being situated opposite the photodetector relative to the steering wheel portion.

The most obvious application is, of course, to measuring the angular position of a steering column in a motor vehicle.

Depending on the relative positions of the diode and the photodetector, the system can include a light guide. Preferably, this is provided with an integrated lens to modify the direction of the laser beam towards the photodetector.

The case considered above relates to a steering wheel which is simply moveable in rotation about a fixed axis.

It is also possible to take into account a configuration with a steering wheel mounted on a connection of swivel-joint type. In this case, the switch of the invention is very similar to the preceding one and can also include at least one circular steering wheel portion the central shaft of which is moveable by means of a swivel-joint, the circular portion including in this case at least two concentric tracks of holograms, the diode emitting a beam substantially parallel with the axis of rotation perpendicular to the median plane of the steering wheel and being situated opposite the photodetector relative to the steering wheel.

In accordance with another possible modification, the laser diode and the photodetector can be arranged inside two portions of fixed concentric spheres each having an orifice coaxial with the orifice of the other, a third portion of sphere, housed and guided between the other two, being provided on its inside face with holograms and including on its outside face a control lever passing through the above-mentioned orifices, the innermost sphere being transparent to light.

In the field of the motor vehicle industry, such switches can for example be applied to control levers for positioning rear-view mirrors.

In all cases, the holograms forming the elementary coding cells can be formed on the face of a sheet material, the other face of which is covered with an adhesive material.

All these contactless solutions meet new requirements expressed for example by motor vehicle constructors relating to the reliability and lifetime of the components used. They also allow application of switching solutions in contexts in which constraints are very tight.

Lastly, they offer great flexibility in that on-demand programming of the detected codes, by means of micro-controllers processing the detected signals, allows easy operational modifications since only the program has to be changed. Moreover, the software basis of the switches allows the number of functions demanded to be multiplied.

### BRIEF DESCRIPTION OF THE DRAWINGS

The invention will now be described in more detail, with reference to the attached figures, in which:

FIG. 1 shows a partial longitudinal section of a switch of ring type;

FIG. 2 is a partial section of the view of FIG. 1;

FIG. 3 is a perspective view of a sliding configuration;

FIG. 4 is a perspective view of a rotary configuration of steering wheel type; and

FIG. 5 is a perspective view of a configuration with a portion of sphere of joystick type.

### DESCRIPTION OF THE PREFERRED EMBODIMENT

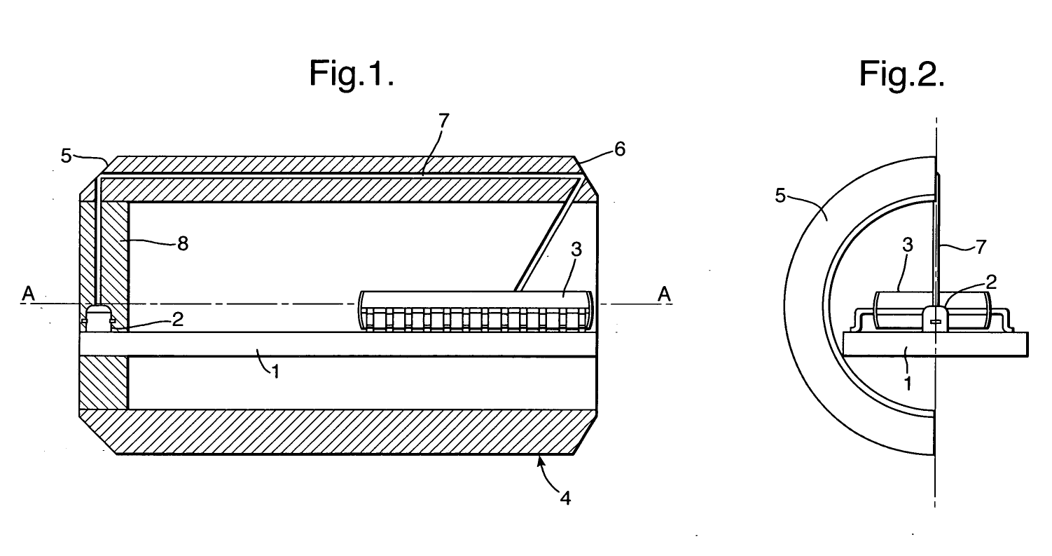

With reference to FIG. 1, the fixed part is formed of a support (1) of printed circuit type on which are arranged on the one hand a laser diode (2) and on the other a photodetector (3). The rotary casing (4) includes two bevelled ends (5) and (6) reflecting light. The laser beam (7) emitted by the diodes (2) perpendicularly to the axis of rotation (A) is emitted, due to the positioning of the laser diode (2), towards the reflective surface (5), which is orientated at 45° so that the said beam (7) is then returned parallel with the axis of rotation (A) towards the other reflective surface (6), and then reflected towards the photodetector (3).

Before reflection on the reflective surface (5), the laser beam passes through an annular zone (8) covered with a track of computer-generated holograms combined with diffractive lenses. The diffracted laser beam (7) contains data relating to the instantaneous position of the ring (4) relative to the fixed support, in this case the printed circuit (1). Where such a rotary sensor is used for example as a ring in the vicinity of the free end of a steering wheel lever, the assembly formed of the printed circuit (1), the laser diode (2) and the photodetector (3) is fixedly connected to the body of the lever. FIG. 2, showing the circular geometry of this solution, explains how it can naturally be embedded in a steering wheel lever.

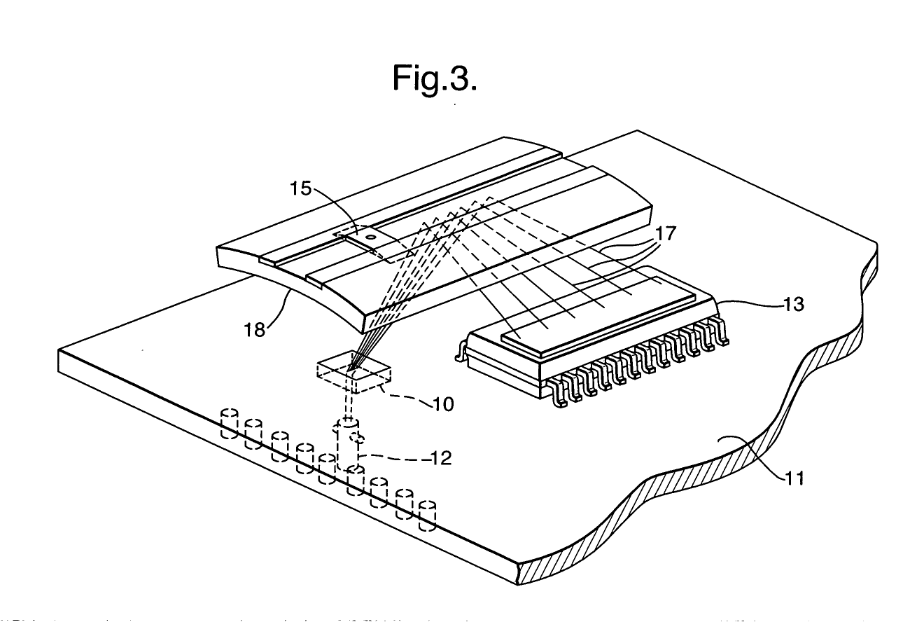

The configuration shown in FIG. 3 also includes, as fixed system, a printed circuit (11) on which are arranged on the one hand a laser diode (12) and on the other a photodetector (13). The initial signal (7) emitted by the laser diode (12) passes through a light divider (10) which splits the initial laser beam (7) into a plurality of beams arranged in a same plane. These laser beams are directed towards a track of holograms (18), i.e. a line of coding cells orientated in the direction of the axis of a support (14) forming a rail for guiding the sliding of a slide (15) covered with a reflective material. The said support (14), which is transparent, acts as a light guide and, depending on the position of the slide (15), one to two split beams (16) are reflected towards the photodetector (13). The position of the slide is consequently known, since the reflected beam contains data relating to the hologram through which it has passed.

In accordance with an alternative sliding solution, the slide is provided with an axial track of holograms which each has a coding function (binary code) and a deflection function, which then allows recovery at the photodetector of the succession of codes inscribed on the axial track moving in front of the photodetector. The signal emitted by the laser diode is not then divided.

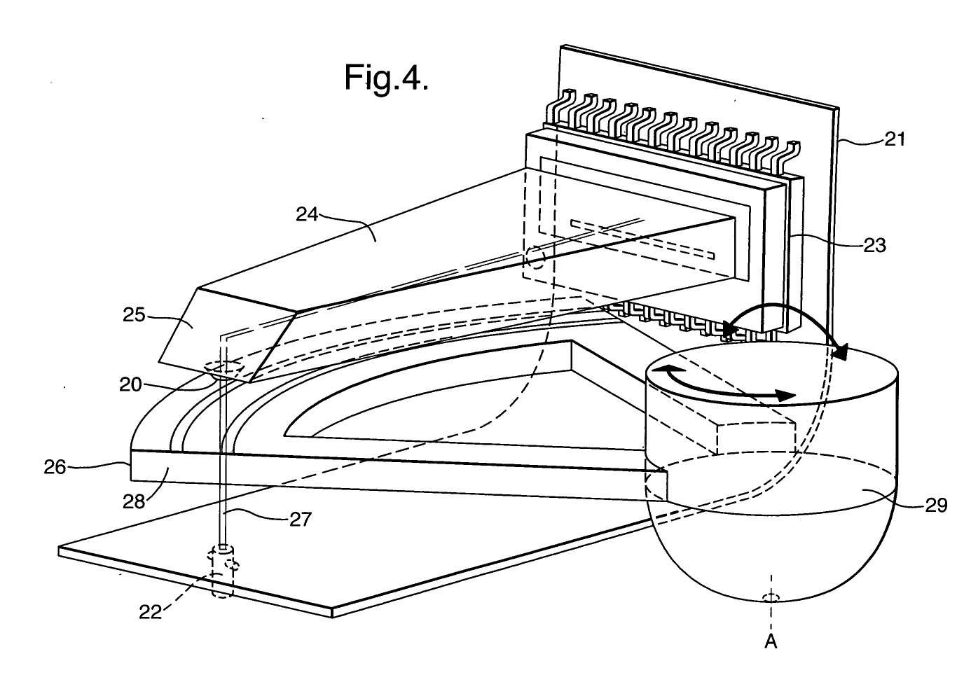

A rotary modified embodiment of the invention is shown in FIG. 4. In this case, a portion of a steering wheel represented by an angular section (26) is connected to a steering column (29) by radial arms. The steering wheel (26) is moveable in rotation about an axis (A). The angular sector proper is covered with a circular encoding track (28) including in this case holograms in the form of position coding cells, and it is made of a light-guiding material. The laser beam (27) from the laser diode (22) passes through the said steering wheel, is optically processed by passage in the track (28), sent to a light guide (24) via an integration lens (20) and then, when necessary, reorientated in the said light guide (24) by means of a mirror (25) correctly orientated relative to the position of the photodetector (23). The fixed elements of the type of the laser diode (22) and photodetector (23) are, as in the preceding solutions, integrated in a same printed circuit (21).

The data read by the photodetector (23) obviously depend on the angular position of the steering wheel (26), which position is expressed by the coding of the holograms arranged on the track (28).

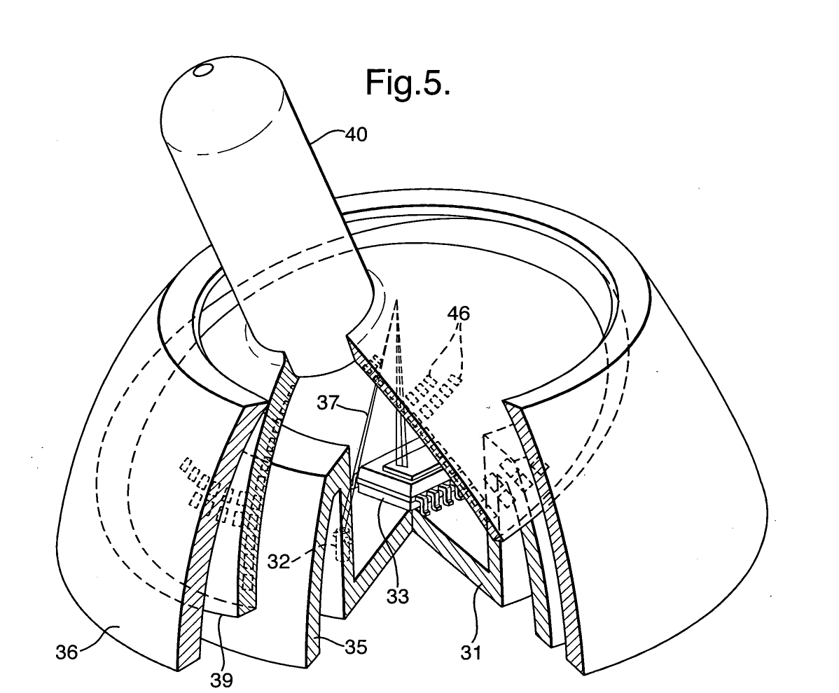

The configuration shown in FIG. 5 is that which is for example used by switches permitting adjustment of the position of exterior rear-view mirrors of vehicles. This application requires a large number of coding cells as the mirror can be adjusted, in three dimensions, into a large number of possible positions. The three-dimensional solution with portions of sphere of FIG. 5 permits implementation of these numerous possibilities. In this case, the fixed system is again composed of a printed circuit (31) on which are arranged a diode (32) and a photodetector (33), to which are added the portions of sphere (35) and (36) open at their tops, permitting guiding of a third portion of sphere (39) rigidly attached to a lever (40), on the inside face of which are arranged the computer-generated hologram cells (46). The sphere (35) is transparent. The laser beam (37) emitted by the laser diode (32) is sent at a predetermined angle of incidence towards the inside wall of the portion of sphere (39) provided with the positioning cells. As a function of the reflection or reflections obtained, a simple calculation performed by the micro-controller permits deduction of the relative position between the portion of sphere (39) and the fixed system.

Other configurations are of course possible, those which have been explained with reference to the attached figures not being able to be considered as limiting to the invention.

1. A switch including a support control organ in motion relative to a fixed device, the organ and the support being in such a relationship that a plurality of distinct relative positions produce differentiatable data producing different effects, wherein the organ or the support includes at least one laser diode emitting a light beam and at least one photodetector, the other including at least one zone situated in the path of the laser beam and provided with computer-generated holograms forming elementary coding cells in order to perform spatial coding of the relative organ/support position, the beam sent by the laser diode being diffracted by the holograms in order to form a binary optical code which can be read by the photodetector and directly and instantaneously transformed into a binary electronic code.

2. The switch of claim 1, wherein the photodetector is connected to a micro-controller.

3. The switch of claim 1, wherein the laser beam passes through guiding/orientation components.

4. The switch of claim 1, wherein the photodetector and the laser diode are arranged on a fixed plate surrounded by a rotary drum made of light-guiding material the ends of which are bevelled and reflect light, the laser diode and the photodetector being located on the plate in such a manner that the beam from the diode is sent to the photodetector after two reflections on the reflective bevelled ends, an annular track of holograms being placed inside the drum in the path of the laser beam.

5. The switch of claim 4, wherein the annular track of holograms is located between the laser diode and the first reflection.

6. The switch of claim 4, wherein the holograms are combined with a grating of diffractive lenses.

7. The switch of claim 1, comprising a fixed laser diode, light-dividing component, hologram support and photodetector, the hologram support being formed of a material transparent to light and acting as a guide rail for a slide provided with a light-reflecting mirror, the laser beam being divided into a plurality of beams directed towards the slide rail via a track of holograms orientated along the slide axis, at least one of the said beams being reflected towards the photodetector depending on the position of the slide.

8. The switch of claim 7, wherein the light-dividing component is a dividing grating.

9. The switch of claim 1, comprising a laser diode, and an organ transparent to light including a slide rail guiding a slide, the face of which orientated towards the diode includes a track of holograms orientated along the slide axis, the elementary cells of the holograms simultaneously performing coding and deflection towards the photodetector.

10. The switch of claim 1, wherein the holograms are combined with a grating of refractive lenses.

11. The switch of claim 1, comprising at least one circular portion of a steering wheel moving in rotation, on which is placed a track of holograms, the diode emitting a beam substantially parallel with the axis of rotation and being situated opposite to the photodetector relative to the steering wheel.

12. The switch of claim 1, comprising at least one circular portion of a steering wheel the central shaft of which is moveable by means of a swivel-joint, the circular portion including at least two concentric tracks of holograms, the diode emitting a beam substantially parallel with the axis of rotation perpendicular to the median plane of the steering wheel and being situated opposite to the photodetector relative to the steering wheel.

13. The switch of claim 11, further comprising a light guide.

14. The switch of claim 13, wherein the light guide includes an integrated lens intended to modify the direction of the laser beam towards the photodetector.

15. The switch of claim 1, wherein the laser diode and the photodetector are arranged inside two fixed concentric portions of sphere each having an orifice coaxial with the orifice of the other, a third portion of sphere, housed and guided between the other two, being provided on its inside face with holograms and including on its outside face a control lever passing through the said orifices, the innermost sphere being transparent to light.

16. The switch of claim 1, wherein the holograms are formed on a face of a sheet material, the other face of which is covered with an adhesive material.
